(19) United States
(12) Patent Application Publication
(10) Pub. No.: US 2026/0206344 A1
(43) Pub. Date: Jul. 16, 2026

(54) IMAGE SENSOR

(71) Applicant: Samsung Electronics Co., Ltd., Suwon-si (KR)

(72) Inventors: KEEWON KIM, Suwon-si (KR); Jeongha Shin, Suwon-si (KR); JONGMIN JEON, Suwon-si (KR); JAESUNG HUR, Suwon-si (KR)

(21) Appl. No.: 19/440,741

(22) Filed: Jan. 6, 2026

(30) Foreign Application Priority Data
Jan. 10, 2025 (KR) 10-2025-0004377

(51) Int. Cl. H10F 39/00; H10F 39/18

(52) U.S. Cl. CPC H10F 39/8053; H10F 39/024; H10F 39/182; H10F 39/8063

(57) ABSTRACT

An image sensor includes a substrate having a first surface and a second surface opposing the first surface and comprising photodiode regions spaced apart from each other, a light transmitting layer covering the second surface, a grid disposed on the light transmitting layer, the grid including first and second patterns and an air gap and an adhesion coefficient of the second pattern being greater than an adhesion coefficient of the first pattern, color filters filling openings defined by the grid, and microlenses disposed on the color filters.

### CROSS-REFERENCE TO RELATED APPLICATIONS

This U.S. non-provisional application claims priority under 35 USC § 119 to Korean Patent Application No. 10-2025-0004377, filed on January 10, 2025, in the Korean Intellectual Property Office, the disclosure of which is herein incorporated by reference in its entirety.

### BACKGROUND

The present disclosure relates to an image sensor.

An image sensor is a semiconductor device that converts an optical image into an electrical signal. With the recent advancements in computer and communication industries, demand for high-performance image sensors has expanded across various applications including digital cameras, camcorders, personal communication systems (PCS), gaming devices, security cameras, and medical micro-cameras. Image sensors may be classified into charge-coupled device (CCD) types and complementary metal oxide semiconductor (CMOS) types. A CMOS image sensor includes a plurality of pixels arranged two-dimensionally. Each of the pixels includes a photodiode (PD). The photodiode serves to convert incident light into an electrical signal.

### SUMMARY

The present disclosure provides an image sensor including an air gap within a grid.

According to an embodiment, an image sensor includes a substrate having a first surface and a second surface opposing the first surface and comprising photodiode regions spaced apart from each other, a light transmitting layer covering the second surface, a grid disposed on the light transmitting layer, the grid including a first pattern and a second pattern, wherein an adhesion coefficient of the second pattern is greater than an adhesion coefficient of the first pattern, an air gap formed in an internal space defined by at least the second pattern, color filters filling openings defined by the grid, and microlenses disposed on the color filters.

According to an embodiment, an image sensor includes a substrate having a first surface and a second surface opposing the first surface and comprising photodiode regions spaced apart from each other, a light transmitting layer covering the second surface, a grid disposed on the light transmitting layer, the grid including a first pattern, a second pattern, the second pattern including phosphorus (P) elements, an air gap enclosed within the grid, color filters filling openings defined by the grid, and microlenses disposed on the color filters.

According to an embodiment, an image sensor includes a substrate having a first surface and a second surface opposing the first surface and comprising photodiode regions spaced apart from each other, a light transmitting layer covering the second surface, a grid disposed on the light transmitting layer, the grid including phosphorus (P) elements, an air gap defined, at least in part, by the gird, color filters filling openings of the grid, and microlenses disposed on the color filters.

### BRIEF DESCRIPTION OF DRAWINGS

FIG. 1 is a block diagram of an image sensor according to one or more embodiments.

FIG. 2 is a circuit diagram of pixels included in a pixel array of an image sensor according to one or more embodiments.

FIG. 3 is a plan view of an image sensor according to one or more embodiments.

FIG. 4 is a cross-sectional view taken along line I-I' of FIG. 3.

FIG. 5 is an enlarged cross-sectional view of portion ‘A’ of FIG. 4.

FIG. 6 is an enlarged cross-sectional view corresponding to portion ‘A’ of FIG. 4, illustrating image sensors according to one or more embodiments.

FIGS. 7-9 are enlarged cross-sectional views corresponding to portion ‘A’ of FIG. 4, illustrating image sensors according to one or more embodiments.

FIGS. 10-12 are enlarged cross-sectional views corresponding to portion ‘A’ of FIG. 4, illustrating image sensors according to one or more embodiments.

FIGS. 13-19 are plan views of image sensors according to one or more embodiments.

FIGS. 20-24 are cross-sectional views illustrating a method of manufacturing an image sensor according to one or more embodiments.

FIG. 25 is a cross-sectional view of an image sensor according to one or more embodiments.

FIG. 26 is a cross-sectional view of an image sensor according to one or more embodiments.

FIG. 27 is a cross-sectional view of an image sensor according to one or more embodiments.

### DETAILED DESCRIPTION

The following description with reference to the accompanying drawings is provided to assist in a comprehensive understanding of various embodiments.

Throughout the specification, when a component is described as "including" a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

It will be understood that when an element is referred to as being "connected" or "coupled" to or “on” another element, it can be directly connected or coupled to or on the other element or intervening elements may be present. In contrast, when an element is referred to as being "directly connected" or "directly coupled" to another element, or as “contacting” or “in contact with” another element (or using any form of the word “contact”), there are no intervening elements present at the point of contact. As the state of contact is binary (either in contact or not in contact), it will be appreciated that “contact” has the same scope as any use of “direct contact.”

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

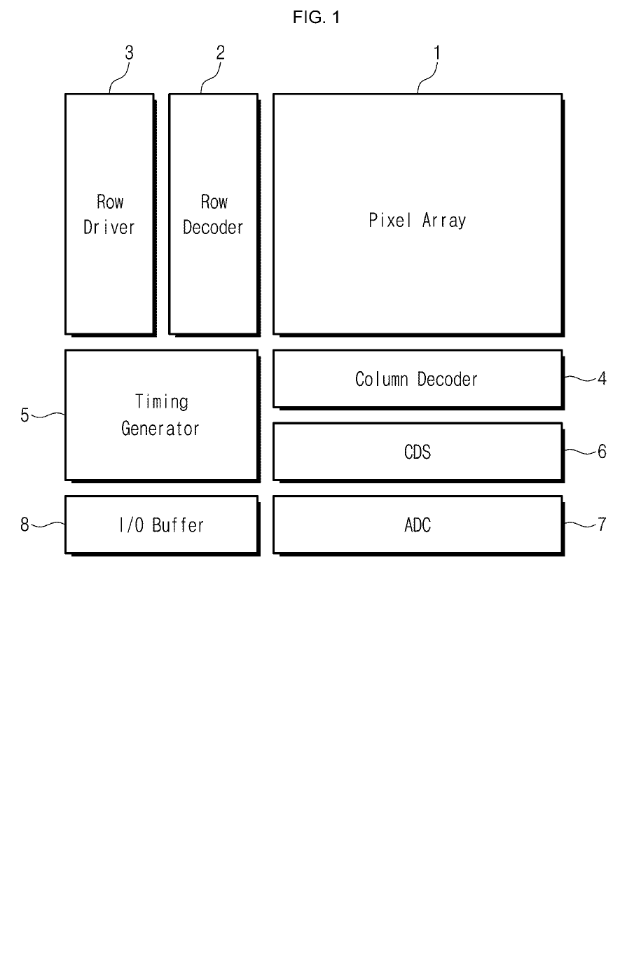

FIG. 1 is a block diagram of an image sensor according to one or more embodiments.

Referring to FIG. 1, an image sensor 10 according to one or more embodiments may include a pixel array 1, a row decoder 2, a row driver 3, a column decoder 4, a timing generator 5, a correlated double sampler (CDS) 6, an analog-to-digital converter (ADC) 7, and an input/output buffer (I/O buffer) 8.

The pixel array 1 may include a plurality of pixels arranged two-dimensionally. The pixels may convert optical signals into electrical signals. The pixel array 1 may be driven by a plurality of driving signals, such as a pixel select signal, a reset signal, a charge transfer signal, or the like, transmitted from the row driver 3. The converted electrical signals may be provided to the correlated double sampler 6.

The row driver 3 may provide a plurality of driving signals to the pixel array 1 to drive the plurality of pixels based on a decoding results from the row decoder 2. When the pixels are arranged in a matrix, the driving signals may be provided in units of rows.

The timing generator 5 may provide timing signals and control signals to the row decoder 2 and the column decoder 4.

The correlated double sampler 6 may receive electrical signals generated by the pixel array 1, and hold and sample the received signals. The correlated double sampler 6 may perform double sampling on the electrical signal to determine a specific noise level and a signal level and then output a difference level corresponding to a difference between the noise level and the signal level.

The analog-to-digital converter 7 may convert an analog signal corresponding to the difference level, output from the correlated double sampler 6, into a digital signal and output the digital signal.

The input/output buffer 8 may latch digital signals and sequentially output the latched signals to an image signal processor, not illustrated, based on the decoding results from the column decoder 4.

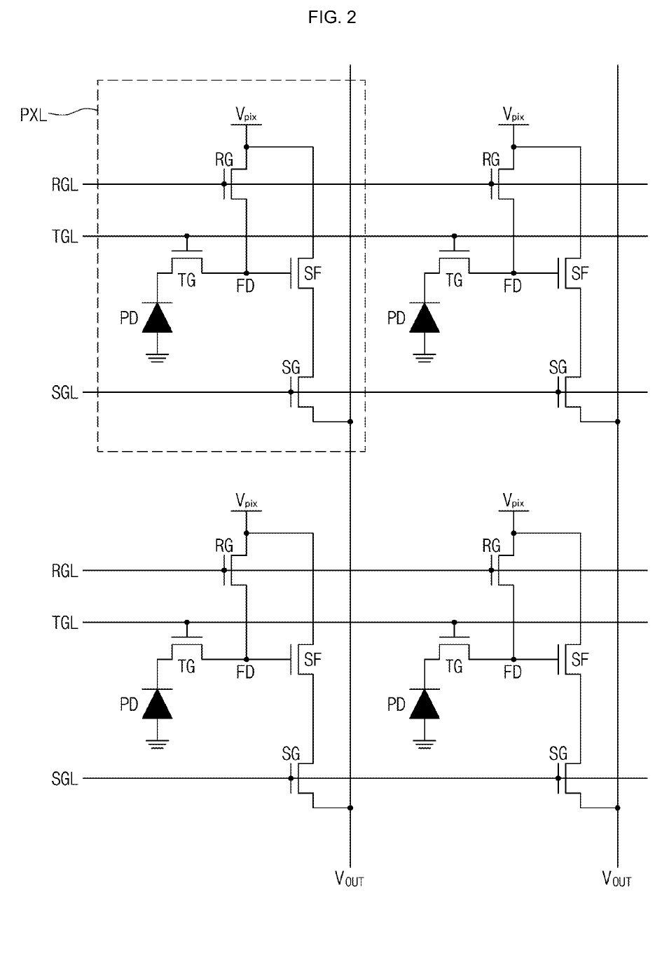

FIG. 2 is a circuit diagram of pixels included in a pixel array 20 of an image sensor according to one or more embodiments.

Referring to FIG. 2, the pixel array 20 may include a plurality of pixels PXL, and the pixels PXL may be arranged in a matrix. Each of the pixels PXL may include pixel transistors, and the pixel transistors may include a transfer transistor TG and logic transistors RG, SG, and SF. The logic transistors RG, SG, and SF may include a reset transistor RG, a select transistor SG, and a source follower transistor SF. In addition, each of the pixels PXL may include a photodiode PD and a floating diffusion region FD.

The photodiode PD may generate and accumulate photocharges in proportion to the amount of light incident from the outside. The photodiode PD may include a photoelectric conversion element, a phototransistor, a photogate, a pinned photodiode, or combinations thereof. The transfer transistor TG may transfer photocharges, generated by the photodiode PD, to the floating diffusion region FD. A transfer gate of the transfer transistor TG may be connected to a transfer gate line TGL. The floating diffusion region FD may receive and cumulatively store photocharges generated by the photodiode PD.

A gate of the source follower transistor SF may be connected to the floating diffusion region FD. One source/drain electrode of the source follower transistor SF may be connected to a power supply voltage Vₚᵢₓ. The source follower transistor SF may be controlled based on the amount of photocharges accumulated in the floating diffusion region FD.

The reset transistor RG may periodically reset the charges accumulated in the floating diffusion region FD. A gate of the reset transistor RG may be connected to a reset gate line RGL. Source/drain electrodes of the reset transistor RG may be connected to a floating diffusion region FD and a power supply voltage Vₚᵢₓ, respectively. For example, a power source/drain electrode of the reset transistor RG may be connected to the power supply voltage Vₚᵢₓ, and the reset source/drain electrode of the reset transistor RG may be connected to the floating diffusion region FD. When the reset transistor RG is turned on, a power voltage from the power supply voltage Vₚᵢₓ may be applied to the floating diffusion region FD through the reset transistor RG. For example, when the reset transistor RG is turned on, the charges accumulated in the floating diffusion region FD may be discharged by the power voltage to reset the floating diffusion region FD.

The source follower transistor SF may function as a source follower buffer amplifier. The source follower transistor SF may amplify a potential change in the floating diffusion region FD and output the amplified potential change to an output line V_{OUT}.

A gate of the select transistor SG may be connected to a selection gate line SGL. Source/drain electrodes of the select transistor SG may be connected to the other source/drain electrode of the source follower transistor SF and an output line V_{OUT}, respectively. The select transistors SG of the pixels PXL to be read in units of rows may be selected by a select signal applied through a corresponding select gate line SGL. When the select transistor SG is turned on, the potential change amplified by the source follower transistor SF may be output to an output line V_{OUT} through the select transistor SG.

Each of the pixels PXL has a single photodiode PD as illustrated in FIG. 2, but embodiments are not limited thereto. In one or more embodiments, a plurality of pixels PXL may share a floating diffusion region FD and logic transistors RG, SG, and SF.

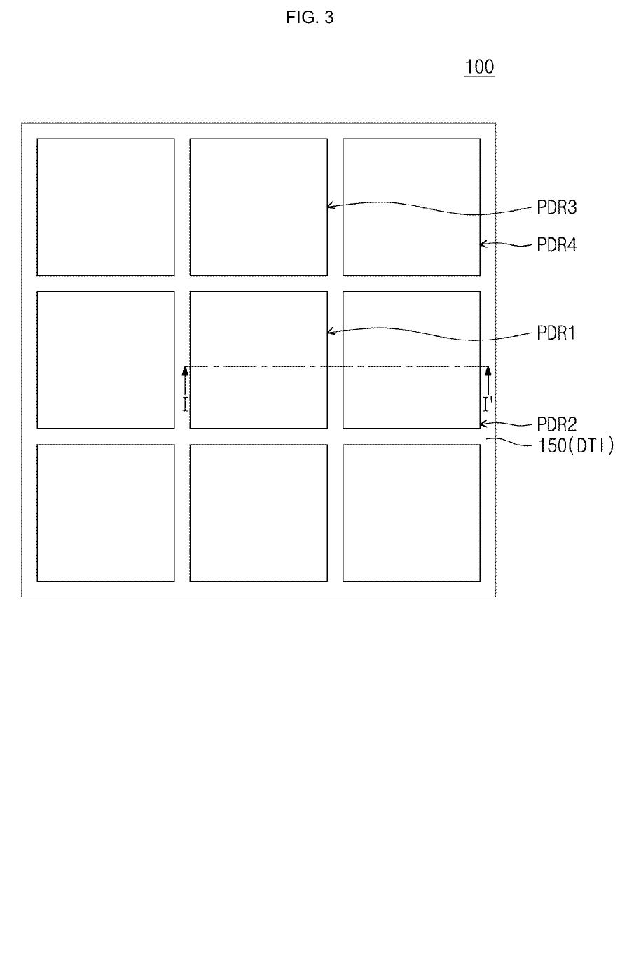

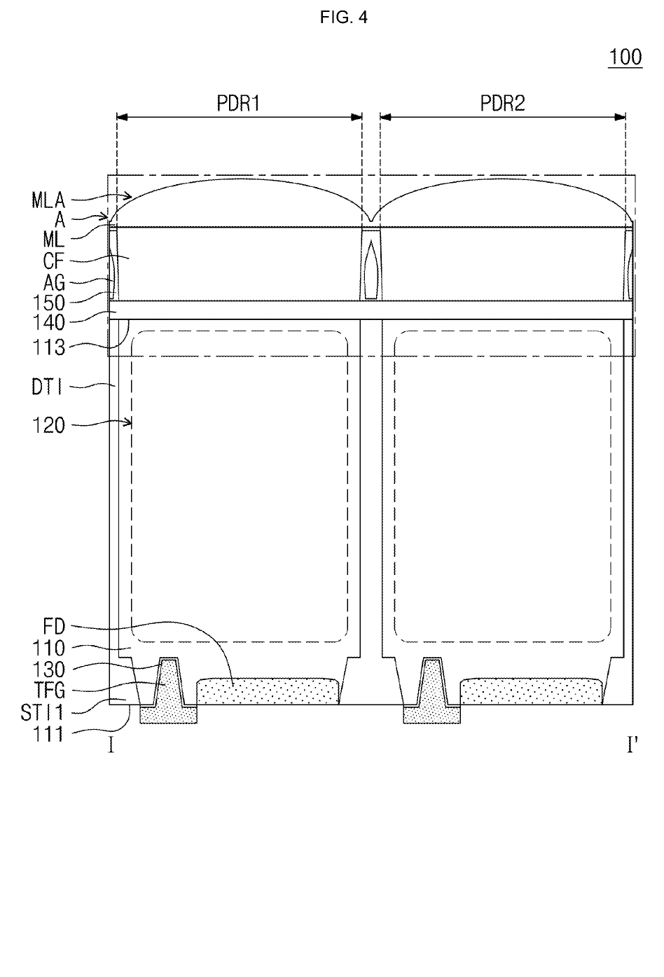

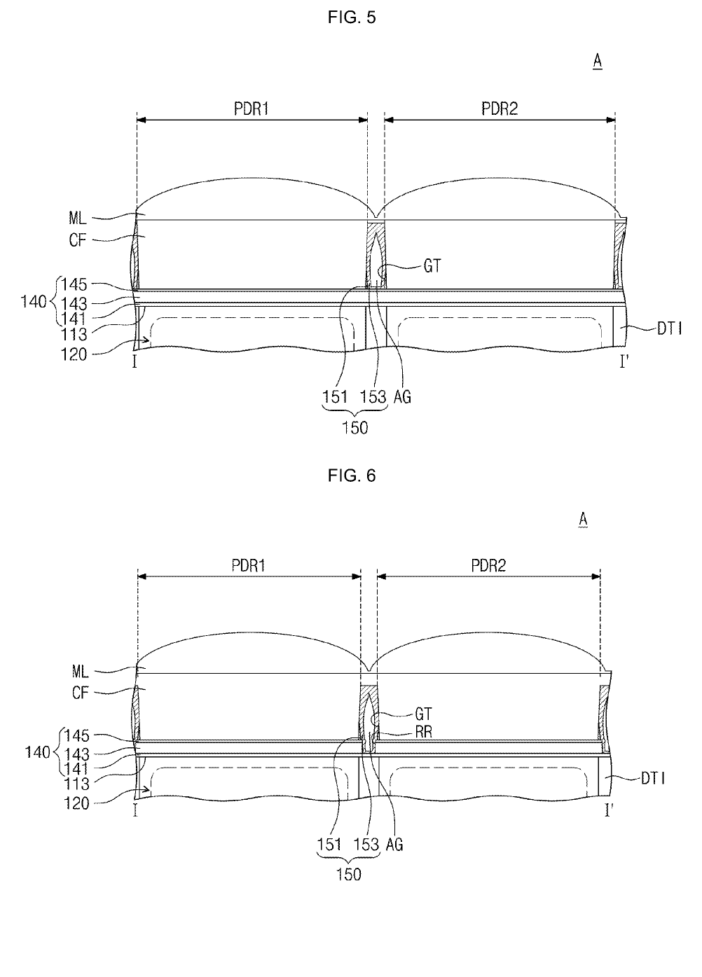

FIG. 3 is a plan view of a photoelectric conversion structure 100 of an image sensor according to one or more embodiments. FIG. 4 is a cross-sectional view taken along the line I-I' of FIG. 3. FIG. 5 is an enlarged cross-sectional view of portion ‘A’ of FIG. 4.

Referring to FIG. 3, an image sensor according to one or more embodiments may include a plurality of photodiode regions PDR. The plurality of photodiode regions PDR may be arranged two-dimensionally. For example, in plan view of FIG. 3, a second photodiode region PDR2 may be provided to the right of a first photodiode region PDR1, a third photodiode region PDR3 may be provided above the first photodiode region PDR1, and a fourth photodiode region PDR4 may be provided in an upper-right diagonal direction of the first photodiode region PDR1.

A deep trench isolation pattern DTI may be provided between the plurality of photodiode regions PDR1 to PDR4. In plan view, the deep trench isolation pattern DTI may be formed to surround each of the photodiode regions PDR1 to PDR4 and physically and electrically separate the photodiode regions PDR1 to PDR4 by spacing the photodiode regions PDR1 to PDR4 apart from each other. In plan view, the deep trench isolation pattern DTI may be disposed in a mesh or grid shape. In one or more embodiments, the deep trench isolation pattern DTI may extend between the plurality of photodiode regions PDR1 to PDR4. For example, the deep trench isolation pattern DTI may extend between the first photodiode region PDR1 and the second photodiode region PDR2, between the first photodiode region PDR1 and the third photodiode region PDR3, between the second photodiode region PDR2 and the third photodiode region PDR3, and between the third photodiode region PDR3 and the fourth photodiode region PDR4.

A grid 150 may be provided on the deep trench isolation pattern DTI. From a plan view, the grid 150 may at least partially overlap with the deep trench isolation pattern DTI. The grid 150 may extend along the boundaries between the photodiode regions PDR1 to PDR4 from a plan view. For example, the grid 150 may extend between the first photodiode region PDR1 and the second photodiode region PDR2, between the first photodiode region PDR1 and the third photodiode region PDR3, between the second photodiode region PDR2 and the third photodiode region PDR3, and between the third photodiode region PDR3 and the fourth photodiode region PDR4.

Referring to FIG. 4, an image sensor according to one or more embodiments may include a photoelectric conversion structure such as photoelectric conversion structure 100. The photoelectric conversion structure 100 may include a first substrate 110, a photodiode 120, a deep trench isolation pattern DTI, a first shallow trench isolation pattern STI1, a floating diffusion region FD, a transfer gate TFG, a gate insulating layer 130, a light transmitting layer 140, a grid 150, an air gap AG, a color filter CF, and a micro lens ML.

The first substrate 110 may have a first surface 111 and a second surface 113 opposing the first surface 111. The first surface 111 may be a front surface of the first substrate 110, and the second surface 113 may be a rear surface of the first substrate 110. Light may be incident on the second surface 113 of the first substrate 110. For example, the second surface 113 of the first substrate 110 may be a light incident surface.

The first substrate 110 may be a silicon (Si) substrate, a germanium (Ge) substrate, a silicon-germanium (Si-Ge) substrate, a Group II-VI compound semiconductor substrate, a Group III-V compound semiconductor substrate, or a silicon-on-insulator (SOI) substrate. The first substrate 110 may include impurities of a first conductivity type, and thus, the first substrate 110 may have the first conductivity type. The impurities of the first conductivity type may be Group III elements. For example, the impurities of the first conductivity type may include P-type impurities such as aluminum (Al), boron (B), indium (In), and/or gallium (Ga).

A plurality of photodiode regions PDR1 and PDR2 may be provided in the first substrate 110. Two photodiode regions PDR1 and PDR2 are illustrated in FIG. 4, but embodiments are not limited thereto. As illustrated in FIG. 3, four photodiode regions PDR1, PDR2, PDR3, and PDR4 may be arranged in a matrix of rows and columns, or five or more photodiode regions may be arranged in a matrix of rows and columns. The photodiode region PDR may correspond to the pixel PXL of FIG. 2.

The photodiode 120 may be provided within the first substrate 110. The photodiode 120 may include impurities having a second conductivity type different from the first conductivity type, and thus, the photodiode 120 may have the second conductivity type. For example, the impurities of the second conductivity type may be Group V elements. For example, the impurities of the second conductivity type may include N-type impurities such as phosphorus, arsenic, bismuth, and/or antimony.

The first substrate 110 and the photodiode 120 may be joined in a P-N junction to form the aforementioned photodiode PD.

In one or more embodiments, a deep trench isolation pattern DTI may be provided within the first substrate 110 to define photodiode regions PDR1 and PDR2 within the first substrate 110, and at least one photodiode 120 may be provided within each of the photodiode regions.

The deep trench isolation pattern DTI may penetrate through the first substrate 110. For example, the deep trench isolation pattern DTI may penetrate through the first and second surfaces 111 and 113 of the first substrate 110 and a substrate body between the first and second surfaces 111 and 113.

In plan view, the deep trench isolation pattern DTI may be formed within the first substrate 110 to surround each of the photodiode regions. For example, the deep trench isolation pattern DTI may be formed by a technique of filling a deep trench, formed by patterning the first substrate 110, with an insulating material (for example, a deep trench isolation (DTI) technique). In one or more embodiments, the photodiode regions PDR1 and PDR2 may be portions of the first substrate 110 surrounded by the deep trench isolation pattern DTI.

In one or more embodiments, the deep trench isolation pattern DTI may include a conductive isolation layer provided within the deep trench and an insulating liner provided between the first substrate 110 and the conductive isolation layer. The conductive isolation layer may include a conductive material such as a doped semiconductor material (for example, doped polysilicon). The conductive isolation layer may be spaced apart from the first substrate 110 by the insulating line to electrically isolate the conductive isolation layer from the first substrate 110 during the operation of the image sensor.

The first shallow trench isolation pattern STI1 may be provided within the first substrate 110 to define active regions. The first shallow trench isolation pattern STI1 may be adjacent to the first surface 111 of the first substrate 110. The first shallow trench isolation pattern STI1 may be provided between active regions to electrically isolate the active regions from each other. In one or more embodiments, the first shallow trench isolation pattern STI1 may define at least one active region within each of the sub-photodiode regions. When a photodiode region does not include sub-photodiode regions, the first shallow trench isolation pattern STI1 may define at least one active region within each of the photodiode regions.

In one or more embodiments, the deep trench isolation pattern DTI may partially overlap the first shallow trench isolation pattern STI1. For example, the deep trench isolation pattern DTI may penetrate through a portion of the first shallow trench isolation pattern STI1. The overlapping portion of the deep trench isolation pattern DTI and the first shallow trench isolation pattern STI1 may correspond to a portion of the first shallow trench isolation pattern STI1 or a portion of the deep trench isolation pattern DTI.

The transfer gate TFG may be disposed on the first surface 111 of the first substrate 110. The transfer gate TFG may be disposed on a corresponding active region (hereinafter referred to as a first active region) of each of the sub-photodiode regions. A first gate insulating layer 130 may be disposed between the transfer gate TFG and the first active region.

The floating diffusion region FD may be provided within the first active region on one side of the transfer gate TFG. In one or more embodiments, the floating diffusion region FD may be a region doped with impurities having the second conductivity type.

In one or more embodiments, a gate spacer, not illustrated, may be provided on side surfaces of the transfer gate TFG. The gate spacer may include an insulating material different from that of the first shallow trench isolation pattern STI1. For example, when the first shallow trench isolation pattern STI1 includes a silicon oxide, the gate spacer may include a silicon nitride and/or a silicon oxynitride.

In one or more embodiments, a capping liner layer, not illustrated, may be disposed on the first surface 111 of the first substrate 110 to conformally cover the first surface 111, the first gate insulating layer 130, the gate spacer, and the transfer gate TFG.

The light transmitting layer 140 may be provided on the second surface 113 of the first substrate 110. The light transmitting layer 140 may cover the second surface 113 of the first substrate 110 and an upper surface of the deep trench isolation pattern. The light transmitting layer 140 may include a transparent insulating material. In one or more embodiments, the light transmitting layer 140 may function as a layer to prevent light reflection and/or as a layer having fixed charges. For example, when the light transmitting layer 140 is used as a layer to prevent light reflection, the light transmitting layer 140 may prevent reflection of light incident on the second surface 113 of the first substrate 110, allowing the light to smoothly reach the photodiode 120. When the light transmitting layer 140 is used as a layer having fixed charges, the light transmitting layer 140 may have negative fixed charges. For example, the light transmitting layer 140 may include a layer having fixed charges and a layer to prevent light reflection, which are sequentially stacked.

Referring to FIG. 5, the light transmitting layer 140 may have a single-layer structure or a multilayer structure. For example, the light transmitting layer 140 may include at least one of a surface insulating layer 141, an antireflective layer 143, or a capping layer 145. However, the structure of the light transmitting layer 140 is not limited thereto. In one or more embodiments, the light transmitting layer 140 may include additional layers besides the surface insulating layer 141, the antireflective layer 143, and the capping layer 145.

The surface insulating layer 141 may be disposed on the second surface 113 of the first substrate 110 and may have at least one function selected from among preventing reflection of light, providing fixed negative charges, or serving as an etch-stop layer. In one or more embodiments, the surface insulating layer 141 may include a metal oxide or metal fluoride containing at least one of aluminum (Al), hafnium (Hf), zirconium (Zr), lanthanum (La), titanium (Ti), tantalum (Ta), or yttrium (Y). For example, the surface insulating layer 141 may be formed of at least one of an aluminum oxide, a hafnium oxide, a zirconium oxide, a lanthanum oxide, a hafnium silicon oxide, a hafnium aluminum oxide, a titanium oxide, or a tantalum oxide. For example, the surface insulating layer 141 may be formed of a titanium oxide, a hafnium oxide, or an aluminum oxide.

The antireflective layer 143 may cover an upper surface of the surface insulating layer 141 disposed on the second surface 113 of the first substrate 110 and may prevent light reflection. In one or more embodiments, the antireflective layer 143 may include an oxide or nitride containing at least one of silicon or hafnium. For example, the antireflective layer 143 may be formed of at least one of a silicon oxide, a silicon nitride, a silicon oxynitride, a hafnium oxide, or a hafnium nitride.

The capping layer 145 may be provided on the antireflective layer 143 to cover the antireflective layer 143. For example, the surface insulating layer 141 and the antireflective layer 143 may be disposed between a second surface 113 of the first substrate 110 and the capping layer 145. The capping layer 145 may include at least one of the functions of preventing light reflection or serving as an etch-stop layer. In one or more embodiments, the capping layer 145 may be formed of at least one of a silicon oxide, a silicon oxynitride, an aluminum oxide, a hafnium oxide, a zirconium oxide, a lanthanum oxide, a hafnium silicon oxide, a hafnium aluminum oxide, a titanium oxide, or a tantalum oxide.

The grid 150 may be provided on the second surface 113 of the first substrate 110 with the light transmitting layer 140 interposed therebetween. For example, the grid 150 may be provided on the light transmitting layer 140. The grid 150 may define openings. A color filter array including two-dimensionally arranged color filters CF may be provided on the second surface 113 of the first substrate 110. The color filter array may be provided on the light transmitting layer 140, and each of the color filters CF may fill corresponding openings of the grid 150. A lens array MLA including two-dimensionally arranged microlenses ML may be provided on the second surface 113 of the first substrate 110 with the color filter array interposed therebetween. For example, the color filter array may be disposed between the lens array and the light transmitting layer 140.

In one or more embodiments, each of the color filters CF may cover corresponding photodiode regions. For example, in plan view, each of the color filters CF may be disposed on four photodiode regions arranged in a 2x2 matrix. For example, each of the color filters CF may cover a pair of adjacent photodiode region groups, but embodiments are not limited thereto. For example, in plan view, each of the color filters CF may be disposed on nine photodiode regions arranged in a 3x3 matrix or on sixteen photodiode regions arranged in a 4x4 matrix.

In one or more embodiments, the color filters CF may include a first color filter having a first color, a second color filter having a second color, and a third color filter having a third color. For example, each of the color filters CF may have one of red, green, or blue colors. Alternatively, each of the color filters CF may have one of cyan, magenta, or yellow colors. The color filters CF may also have colors other than the above-mentioned red, green, blue, cyan, magenta, or yellow colors.

In one or more embodiments, the grid 150 may vertically overlap the deep trench isolation pattern DTI. In one or more embodiments, when the grid 150 is laterally shifted, at least a portion of the grid 150 may not vertically overlap the deep trench isolation patterns DTI. For example, the grid 150 may have a structure, laterally offset from the deep trench isolation patterns DTI. The offset structure may be intentionally selected to optimize the light path in consideration of manufacturing process margins and/or an angle of incident light.

The grid 150 may guide incident light into the photodiode 120. The grid 150 may prevent light, obliquely incident into a color filter CF disposed on a single photodiode region PDR, from entering a color filter CF disposed on an adjacent photodiode region PDR. As a result, crosstalk between the plurality of photodiode regions PDR1 and PDR2 may be prevented.

The grid 150 may have a single-layer structure or a multilayer structure. The grid 150 may include a low-refractive-index material. The low-refractive-index material may refer to a material having a lower refractive index than silicon (Si).

The air gap AG may have a low refractive index, and light incident toward the air gap AG may be totally reflected and directed toward the center of the photodiode region PDR. The air gap AG may be provided or formed within the grid 150. The air gap AG may be defined by an internal space of the grid 150. For instance, the air gap AG may be disposed or formed within the first pattern 151 and the second pattern 153. The first pattern 151 may be or form a grid trench structure GT, which defines a trench. Further, a portion of the second pattern 153 may be provided within the trench defined by the grid trench structure GT to define the air gap AG. Moreover, another portion of the second pattern 153 may close an upper end of the air gap AG. Accordingly, the air gap AG may be defined by the second pattern 153.

It should be appreciated that an “air gap” may comprise a gap having air or other gases (e.g., such as those present during manufacturing) or may comprise a gap forming a vacuum therein. The term “air” as discussed herein, may refer to atmospheric air, or other gases that may be present during the manufacturing process.

In one or more embodiments, the first pattern 151 and the second pattern 153 may be formed of different materials. For example, the first pattern 151 and the second pattern 153 may be formed of materials having different adhesion properties such that the adhesion coefficient of the second pattern 153 may be greater than that of the first pattern 151 in at least one embodiment.

In one or more embodiments, the first pattern 151 may be formed of or include an insulating material, and the second pattern 153 may be formed of or include a doped insulating material. For example, the first pattern 151 may include an insulating material, and the second pattern 153 may include an insulating material containing or doped with phosphorus (P) and/or boron (B) atoms. For instance, the second pattern 153 may be realized as insulating layer containing or doped with phosphorus (P) and/or boron (B) elements.

In some embodiments, the insulating material of the first pattern 151 may be the same as the insulating material of the second pattern 153, except that the insulating material of the second pattern contains or is doped with adhesion promoting elements. In such cases, the insulating material common to both the first pattern and the second pattern can be considered as a base insulating material with only the second pattern containing or being doped with the adhesion promoting elements. For example, the first pattern 151 or the insulating material of the first pattern 151 may be without or free of such adhesion promoting elements, e.g., free of phosphorus (P) and/or boron (B) elements.

As used herein, dopant elements such as “phosphorus element” (and likewise “boron element”) may encompass not only elemental phosphorus (P) or boron (B) atoms, but also phosphorus- or boron-containing compounds or materials capable of supplying, incorporating, or contributing such elements (e.g., phosphorus (P) or boron (B) atoms ) within a material or layer.

In other examples, the insulating material of the first and second patterns 151, 153 may differ from each other. For example, they each may have a different base insulating material. In addition, the insulating material of the second pattern 153 may further contain or be doped with adhesion promoting elements. Further, in such cases the insulating material of the first pattern may be free or without such adhesion promoting elements.

In one or more embodiments, the first pattern 151 may include a silicon oxide (e.g., as a base insulating material), and the second pattern 153 may include a silicon oxide (e.g., as a base insulating material) containing or doped with at least one of phosphorus (P) or boron (B) elements. Examples of phosphorous of such elements include, for example, phosphosilicate glass (PSG), borosilicate glass (BSG), boron phosphosilicate glass (BPSG), or the like. In one or more embodiments, the second pattern 153 may have a phosphorus (P) element concentration of 1 at% to 20 at%. For example, the second pattern 153 may have a phosphorus (P) element concentration (e.g., in PSG) of 1 at% to 20 at%, or a phosphorus dopant concentration within a similar range.

Other base insulating material, e.g., other than silicon oxide, may be used for the first pattern 151 and the second pattern 153.

In one or more examples, the first pattern 151 or at least its insulating material may be free or without such adhesion increasing or promoting dopants. Accordingly, without being bound by theory, the presence of certain dopants, such as phosphorus (P) or boron (B), or elements containing phosphorus (P) or boron (B) may modify the adhesion or sticking characteristics of the insulating material. For instance, incorporation of such dopants or elements into an insulating material such as silicon oxide may increase its adhesion coefficient (or sticking coefficient), thereby influencing its step-coverage behavior as a deposited film.

In one or more embodiments, the volume of the air gap AG may be greater than half of the total volume of the grid 150. For example, the volume of the air gap AG may be greater than 50% of the total volume of the grid 150. For example, the volume of the air gap AG may be 50% to 90% of the total volume of the grid 150. For example, the volume of the air gap AG may be 60% to 80% of the total volume of the grid 150.

The microlens ML may be disposed on the light transmitting layer 140 with the color filter CF interposed therebetween. At least a portion of the microlens ML may vertically overlap the photodiode 120. The microlens ML may focus light incident toward the first substrate 110. In one or more embodiments, the microlens ML may include an organic material such as a polymer. For example, the microlens ML may include a light-transmissive resin, a photoresist material, or a thermosetting resin.

In one or more embodiments, the microlens ML may include a lens pattern and a planarization portion. The planarization portion may be provided on the color filter CF, and the lens pattern may be provided on the planarization portion. The lens pattern may include the same material as the planarization portion. The lens pattern and the planarization portion may form a single body without an interface therebetween. In one or more embodiments, the planarization portion may be omitted, and the lens pattern may be directly disposed on the color filter CF.

In one or more embodiments, each of the microlenses ML may cover a corresponding photodiode region. For example, each of the microlenses ML may vertically overlap a corresponding one of the photodiode regions. In one or more embodiments, each of all the microlenses ML in the lens array may vertically overlap a corresponding one of the photodiode regions. Each of the microlenses ML may be provided to focus incident light and may include a spherical lens, an aspherical lens, or a combination thereof. For example, each of the microlenses ML may have an upwardly convex shape in cross-sectional view.

FIG. 6 is an enlarged cross-sectional view corresponding to portion ‘A’ of FIG. 4, illustrating image sensors according to one or more embodiments. Hereinafter, differences from the above-described embodiments will be mainly described for clarity.

Referring to FIG. 6, the light transmitting layer 140 may include a capping layer 145, a portion of which is penetrated, and an antireflective layer 143, a portion of which is recessed. A portion of the capping layer 145 may be penetrated and a portion of the antireflective layer 143 may be recessed to define a recessed region RR. Accordingly, the antireflective layer 143 and the capping layer 145 may include the recess region RR. The second pattern 153 may extend from the capping layer 145 toward the antireflective layer 143 and the capping layer 145 to fill a portion of the recess region RR. The air gap AG may extend inwardly of a portion of the recess region RR, which remains after being filled with the second pattern 153, to fill a portion of the recess region RR. For example, the air gap AG may be configured to have a larger space within the grid 150 through the recess region RR.

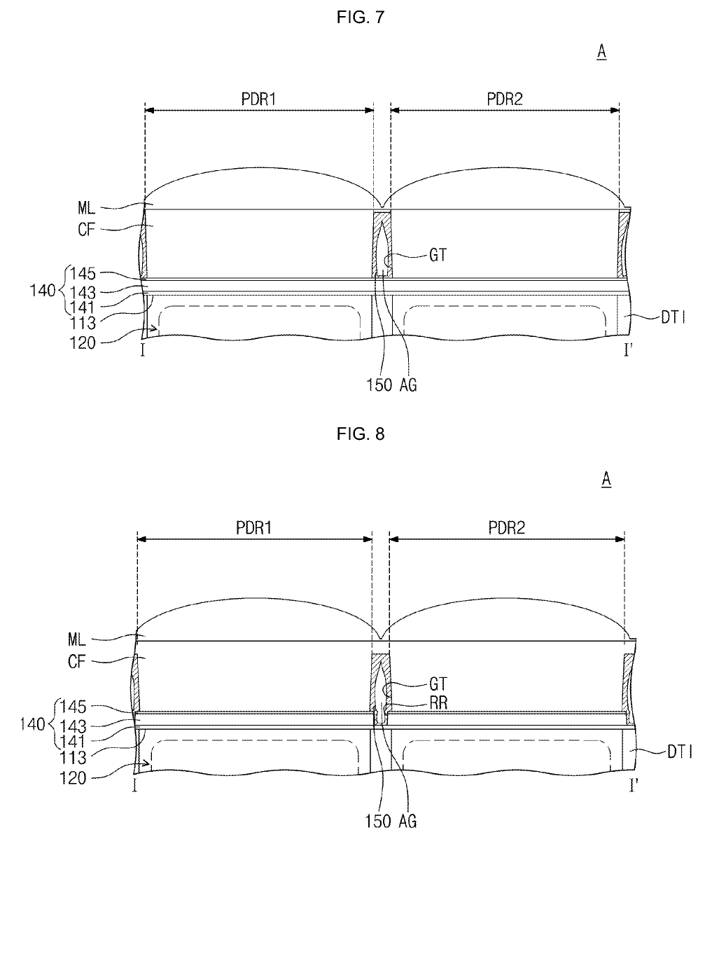

FIGS. 7-9 are enlarged cross-sectional views corresponding to portion ‘A’ of FIG. 4, illustrating image sensors according to one or more embodiments. Hereinafter, differences from the above-described embodiments will be mainly described for brevity.

Referring to FIGS. 7-9, the grid 150 may be formed as a single pattern. For instance, a single pattern may refer to a single continuous monolithic material or a single integral structure. Accordingly, the grid 150 may include an air gap AG defined by an internal space within the grid 150. The grid 150 may be formed after the color filters CF are provided, so that the grid 150 is formed as a single pattern. For example, a sacrificial grid may be disposed, and after placing the color filters CF in the openings of the sacrificial grid, the sacrificial grid may be removed to form a grid trench structure GT. For example, the grid trench structure may be formed by disposing the color filters CF at regular intervals on the capping layer 145. For example, the grid trench structure GT may be formed by disposing the color filters CF on the capping layer 145, placing a grid layer on the color filters CF, and then etching a portion of the color filters CF and the grid layer. The grid 150 may be provided within a portion of the grid trench structure GT, the grid 150 may have an internal space, and the air gap AG may be defined by the internal space.

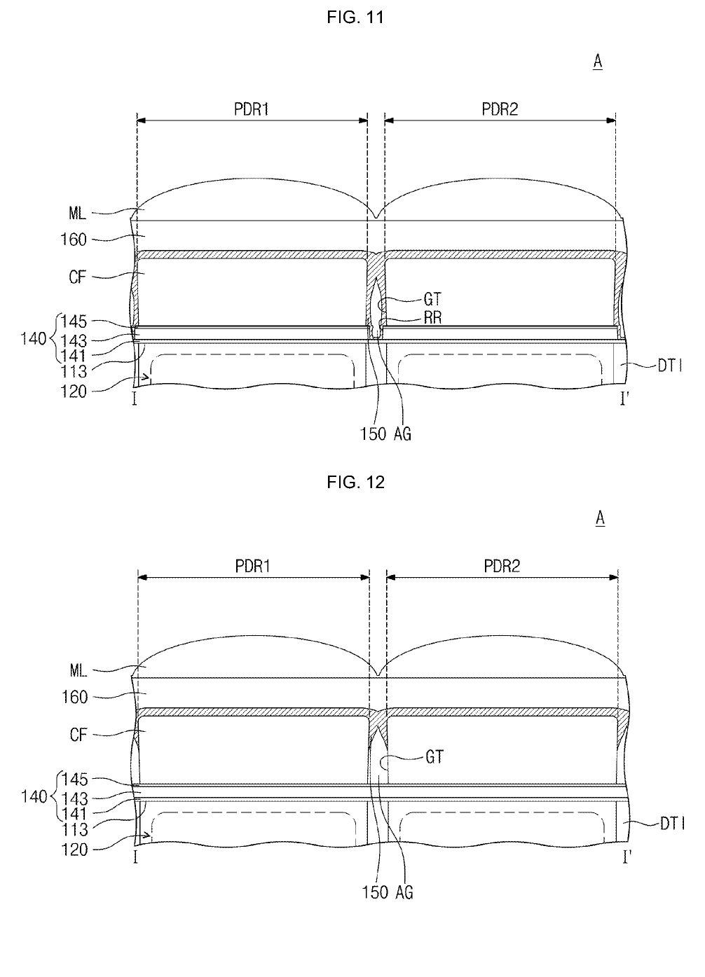

According to one or more embodiments, when the grid 150 is formed after the color filters CF are provided, the grid layer may be disposed on the color filters CF. The grid layer may be provided on the color filters CF and may be removed during an etching process until the color filters CF are exposed. When the grid layer disposed on the color filters CF is not entirely removed, the grid 150 may be formed as illustrated in FIGS. 10 to 12 below.

In one or more embodiments, the grid 150 may include a doped insulating material. For example, the grid 150 may include an insulating material containing phosphorus (P) and/or boron (B) elements or an insulating material doped with phosphorus (P) and/or boron (B) elements. For example, the grid 150 may include a silicon oxide containing or doped with at least one of phosphorus (P) or boron (B) elements. In one or more embodiments, the grid 150 may have a phosphorus (P) element concentration of 1 at% to 20 at%.

Referring to FIG. 8, the antireflective layer 143 may include a recess region RR defined by recessing a portion of the antireflective layer 143. A portion of the grid 150 may extend to the recess region RR of the antireflective layer 143 to fill a portion of the recess region RR. The air gap AG may extend to a portion of the recess region RR, which remains after being filled with the grid 150, to fill a portion of the recess region RR.

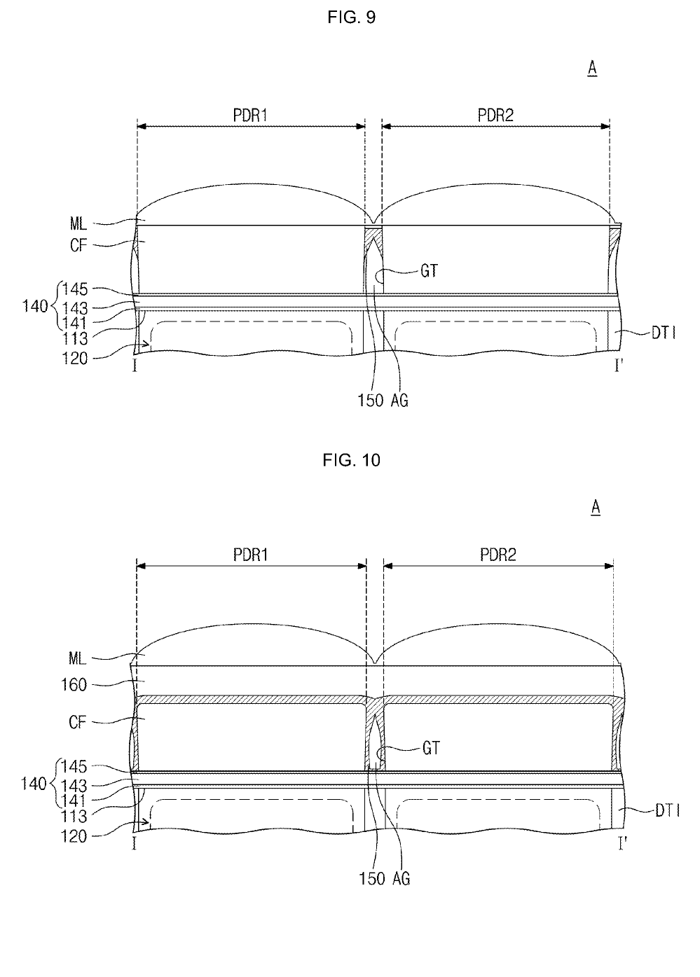

Referring to FIG. 9, the grid trench structure GT may be formed between color filters CF spaced apart from each other on the capping layer 145. The air gap AG may be provided between the color filters CF. For example, the air gap AG may be defined by a space formed by the color filters CF spaced apart from each other, and an upper end of the air gap AG may be covered with the grid 150. Accordingly, the air gap AG may be defined by the capping layer 145, the color filters CF, and the grid 150, a lower surface of the air gap AG may be the capping layer 145, a side surface of the air gap AG may be the color filters CF, and an upper surface of the air gap Ag may be the grid 150. In FIG. 9, a height of the color filters CF is illustrated as being higher than or similar to a height of the grid 150, but embodiments are not limited thereto and the height of the color filters CF may be lower than that of the grid 150.

FIGS. 10-12 are enlarged cross-sectional views corresponding to portion ‘A’ of FIG. 4, illustrating image sensors according to one or more embodiments. Hereinafter, differences from the above-described embodiments will be mainly described for clarity.

Referring to FIGS. 10-12, the grid 150 may extend upwardly of the color filters CF to cover at least a portion of the color filters CF. In FIGS. 10-12, the grid 150 is formed to cover the entirety of the color filters CF, but embodiments are not limited thereto. Therefore, the grid 150 may be formed to cover only a portion of the color filters CF. To form the grid 150 to cover all or a portion of the color filters CF, as described above, a grid trench structure GT may be formed after the color filters CF are provided, a portion of the grid 150 may be provided within the grid trench structure GT, and a portion of the grid 150 may extend upwardly of the color filters CF to cover at least a portion of the color filters CF. An additional light transmitting layer 160 may be formed between the grid 150 and the microlens ML.

The additional light transmitting layer 160 may be provided on all or a portion of the grid 150. The additional light transmitting layer 160 may cover an upper surface of a portion of the grid 150 and an upper surface of the color filters CF. The additional light transmitting layer 160 may include a transparent insulating material. In one or more embodiments, the additional light transmitting layer 160 may function as a layer to prevent light reflection. For example, the additional light transmitting layer 160 may prevent reflection of light incident through the microlens ML, allowing the light to smoothly reach the color filters CF. In one or more embodiments, the additional light transmitting layer 160 may have a single-layer structure or a multilayer structure. For example, the additional light transmitting layer 160 may include at least one of an additional antireflective layer, not illustrated, or an additional capping layer, not illustrated. However, the structure of the additional light transmitting layer 160 is not limited thereto. In one or more embodiments, the additional light transmitting layer 160 may include other layers besides the above-described additional antireflective layer and additional capping layer.

In one or more embodiments, a portion of the upper surface of the grid 150 may be at a position level that is identical or similar to a position level of a portion of the lower surface of the additional light transmitting layer 160. For example, a portion of the upper surface of the grid 150 may be planarized.

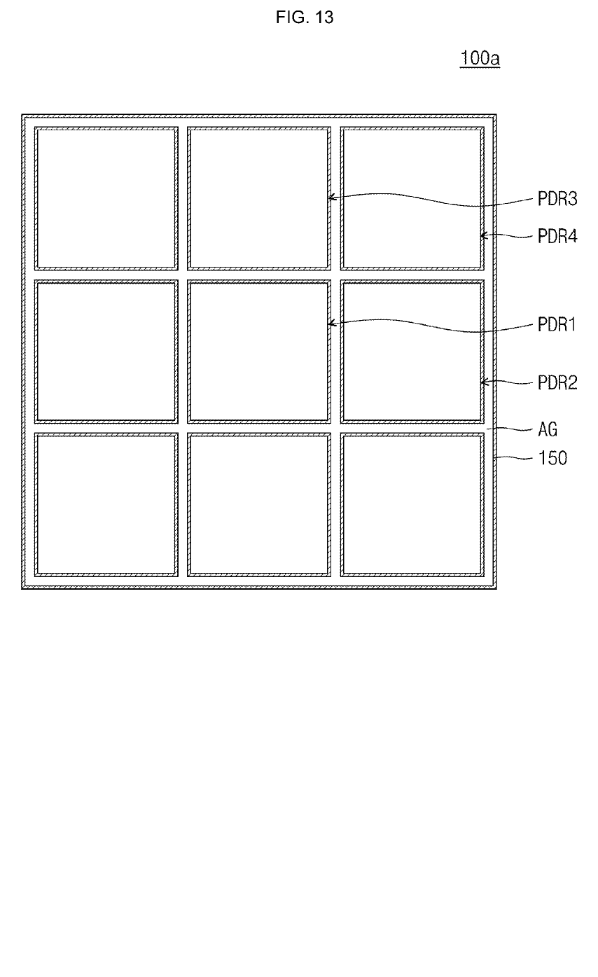

FIGS. 13-19 are plan views of image sensors according to one or more embodiments.

Referring to FIGS. 13-15, a grid 150 may be connected while surrounding photodiode regions PDR1 to PDR4 overall. For example, the grid 150 surrounding the first photodiode region PDR1 may extend to surround the second photodiode region PDR2, the third photodiode region PDR3, and the fourth photodiode region PDR4. In one or more embodiments, the grid 150 may include at least one air gap AG.

Referring to the photoelectric conversion structure 100a of FIG. 13, air gaps AG within the grid 150 may be connected to each other and, in plan view, arranged to surround the plurality of photodiode regions PDR1 to PDR4 overall. For example, the air gap AG may have a grid shape in plan view. The air gap AG illustrated in FIG. 13 may be the air gap AG illustrated in FIGS. 5 to 8. When the air gaps AG illustrated in FIG. 9 are connected to each other to form a single grid, the air gaps AG may have the shape of the grid 150 of FIG. 3 in plan view. Further, as shown in the air gap AG may be a single air gap, extending continuously throughout the grid and thereby has the grid shape. That is, referring to the example of FIG. 13, only a single air gap, extending continuously, may be provided.

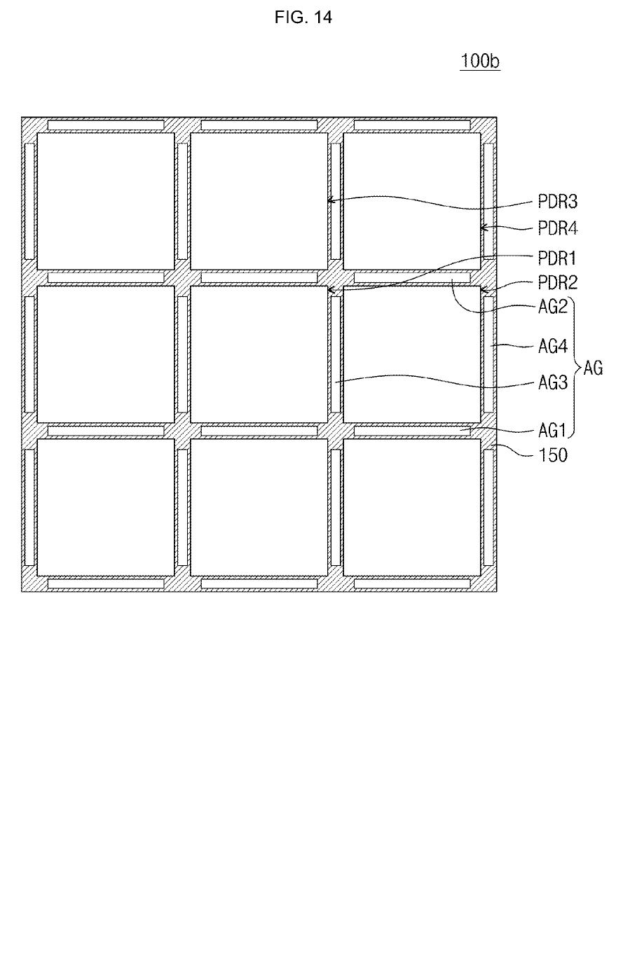

Referring to the photoelectric conversion structure 100b of FIG. 14, in plan view, air gaps AG1 to AG4 within the grid 150 may be spaced apart from each other and arranged to partially surround peripheries of the plurality of photodiode regions PDR1 to PDR4. For example, in plan view, the air gaps AG1 to AG4 may have a bar shape. In one or more embodiments, in plan view, the air gaps AG1 to AG4 may be arranged as follows relative to a single photodiode region PDR2: a first air gap AG1 below the photodiode region PDR2, a second air gap AG2 above the photodiode region PDR2, a third air gap AG3 to the left of the photodiode region PDR2, and a fourth air gap AG4 to the right of the photodiode region PDR2, and each of the air gaps AG1 to AG4 may have the same or similar bar shape size. However, a size of each of the air gaps AG1 to AG4 is not limited, so that the air gaps AG1 to AG4 may have bar shapes of different sizes, and each of the air gaps AG1 to AG4 may be divided and arranged in a number greater than the number of air gaps AG1 to AG4 illustrated.

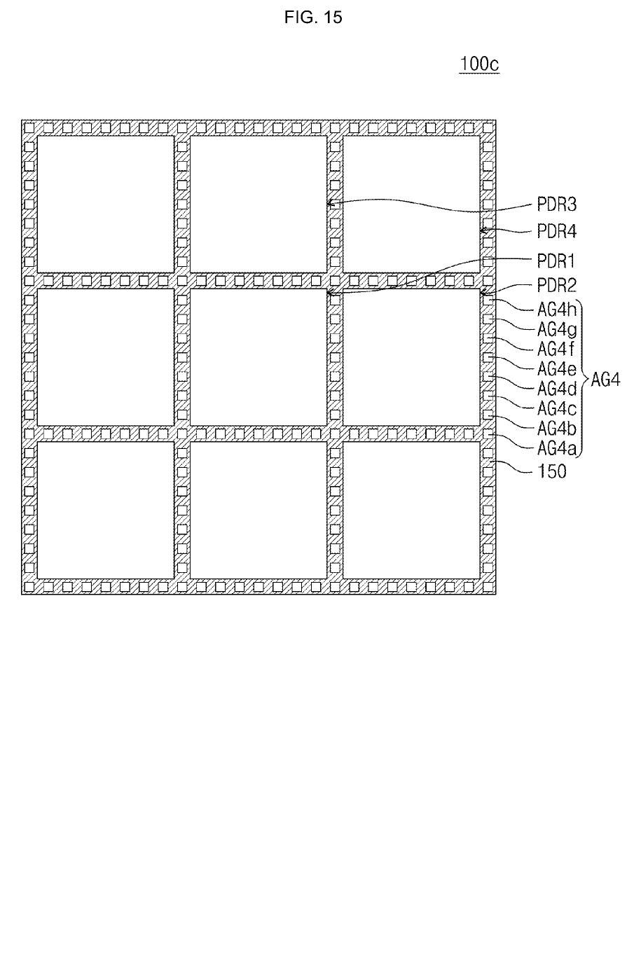

Referring to photoelectric conversion structures 100b and 100c respectively in FIGS. 14 and 15, in plan view, the air gaps AG1 to AG4 within the grid 150 may be spaced apart from each other and arranged to surround the plurality of photodiode regions PDR1 to PDR4 in a dotted pattern. The fourth air gap AG4 disposed to the right of the second photodiode region PDR2 in FIG. 15 may be divided to include a total of eight dot-shaped air gaps AG4a to AG4h, which may be identically or similarly applied to each of the first to third air gaps AG1 to AG3.

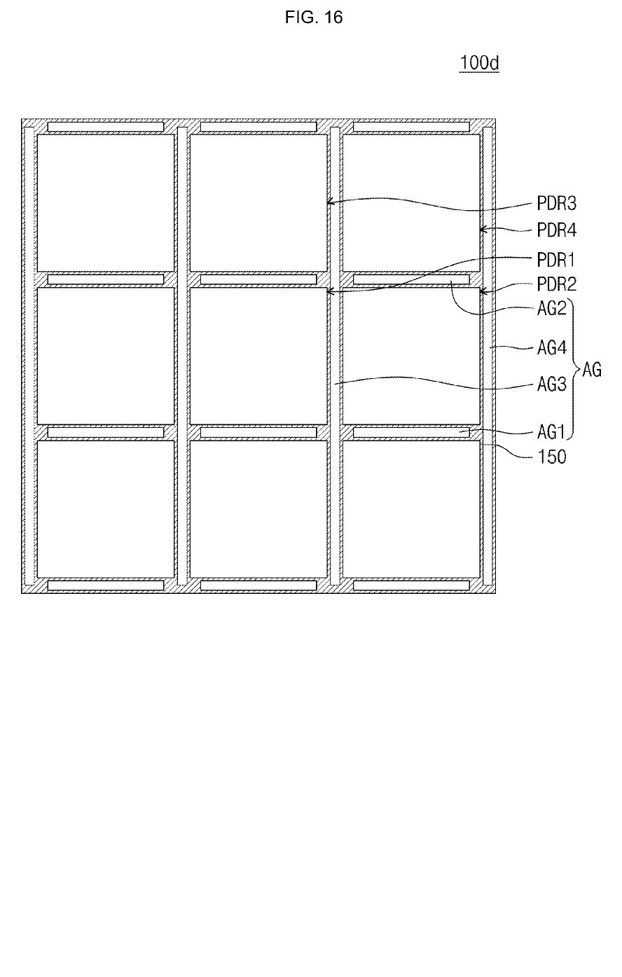

Referring to photoelectric conversion structures 100d-100g found respectively in FIGS. 16 to 19, in plan view, the above-described air gaps AG1 to AG4 may have at least one of a grid shape, a bar shape, or a dot shape.

For example, as illustrated in FIG. 16, the first and third air gaps AG1 and AG3 may have a relatively short bar shape, and the second and fourth air gaps AG2 and AG4 may have a relatively long bar shape separating both a space between the first- and second-photodiode regions PDR1 and PDR2 and a space between the third and fourth photodiode regions PDR3 and PDR4.

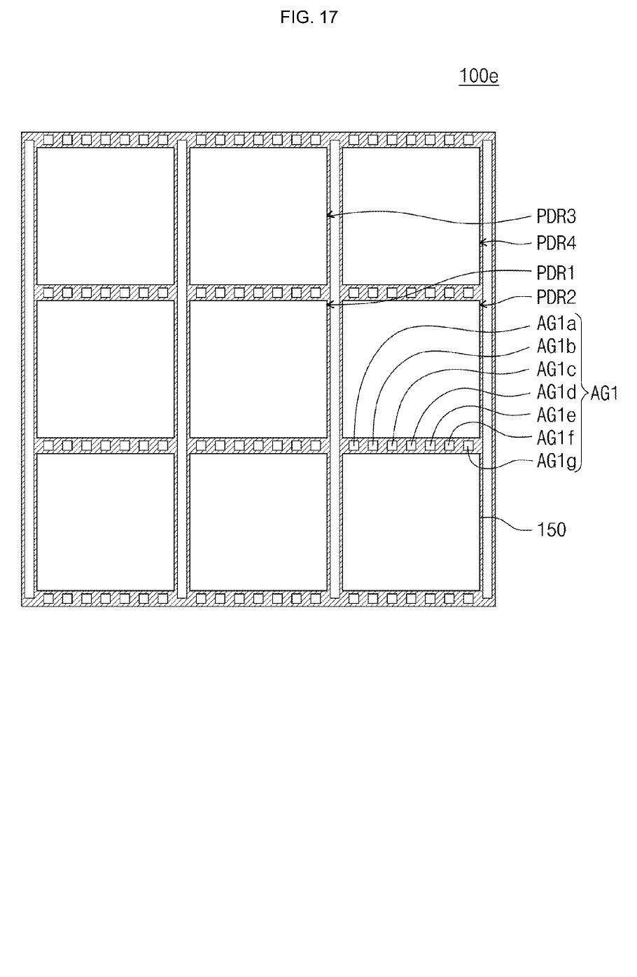

For example, as illustrated in FIG. 17, the first and third air gaps AG1 and AG3 may have a plurality of dot shapes, and the second and fourth air gaps AG2 and AG4 may have a bar shape separating both a space between the first and second photodiode regions PDR1 and PDR2 and a space between the third and fourth photodiode regions PDR3 and PDR4.

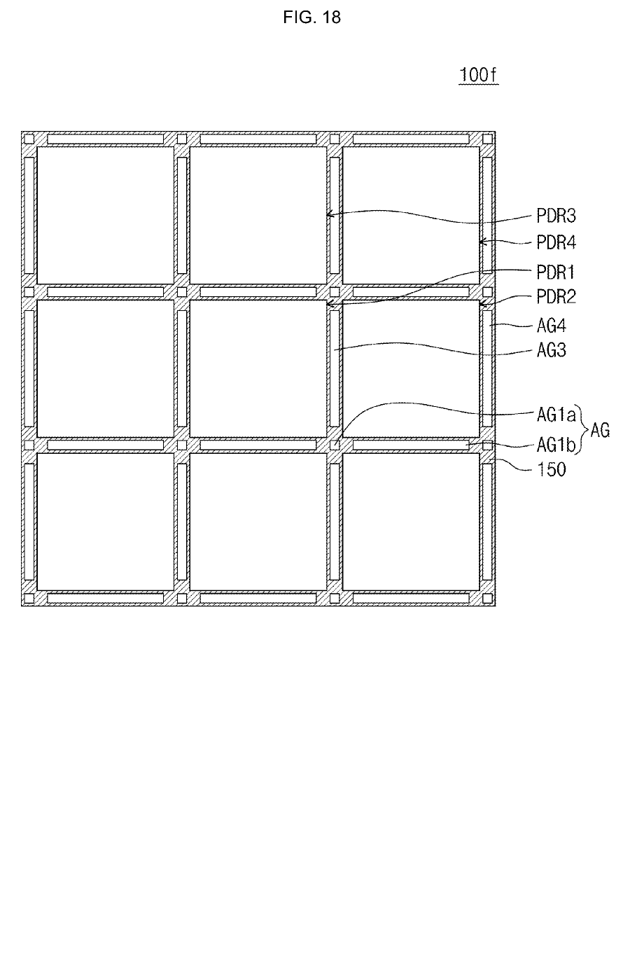

For example, as illustrated in FIG. 18, the first to fourth air gaps AG1 to AG4 may have a short bar shape, and dot-shaped air gaps may be further provided between the respective first to fourth air gaps corresponding to adjacent photodiode regions.

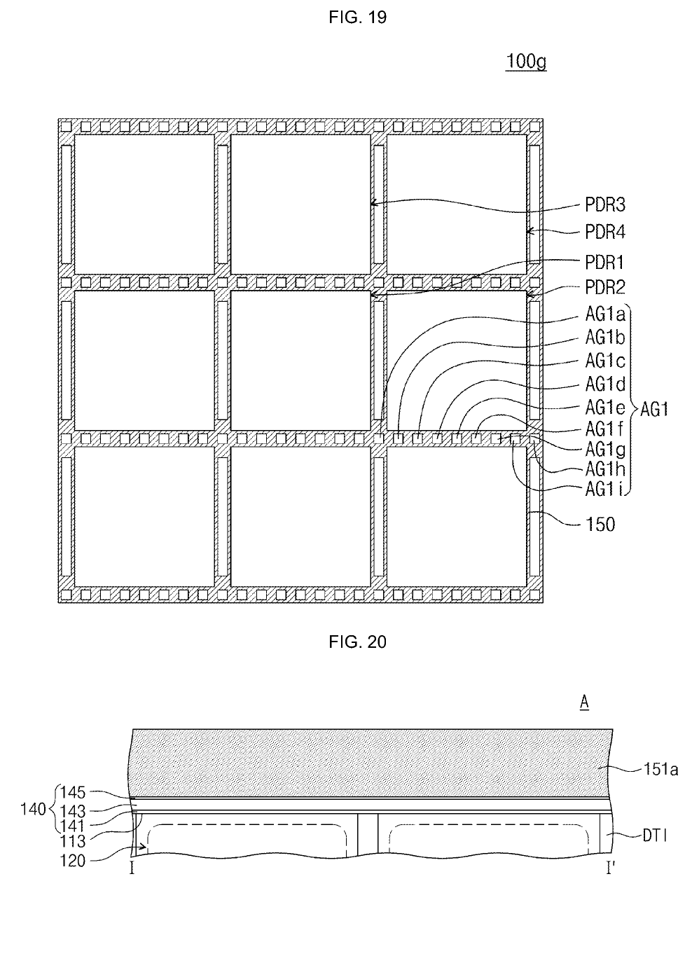

For example, as illustrated in FIG. 19, the first and third air gaps AG1 and AG3 may have a plurality of dot shapes AG1a to AG1i, and the second and fourth air gaps AG2 and AG4 may have a bar shape separating a space between the first and second photodiode regions PDR1 and PDR2.

FIGS. 20 to 24 are cross-sectional views illustrating a method of manufacturing an image sensor according to one or more embodiments. FIGS. 20 to 24 are enlarged cross-sectional views corresponding to portion ‘A’ of FIG. 4.

Referring to FIG. 20, a first substrate 110 having first and second surfaces 111 and 113 may be prepared, and a deep trench isolation pattern DTI may be formed within the first substrate 110. The deep trench isolation pattern DTI may define photodiode regions. Photodiodes 120 may be formed within each of the photodiode regions using an ion implantation process. In one or more embodiments, the photodiodes 120 may be formed before or after the formation of the deep trench isolation pattern DTI. Then, various components (a transfer gate TFG, a floating diffusion region FD, interlayer dielectrics, wirings, or the like) may be formed on the first surface 111 of the first substrate 110. Then, the first substrate 110 may be bonded to another substrate, and the second surface 113 of the first substrate 110 may be planarized. In addition, a surface insulating layer 141 may be formed on the planarized second surface 113 of the first substrate 110, an antireflective layer 143 may be formed on the surface insulating layer 141, and a capping layer 145 may be formed on the antireflective layer 143. In one or more embodiments, a first pattern layer 151a may be formed on the capping layer 145.

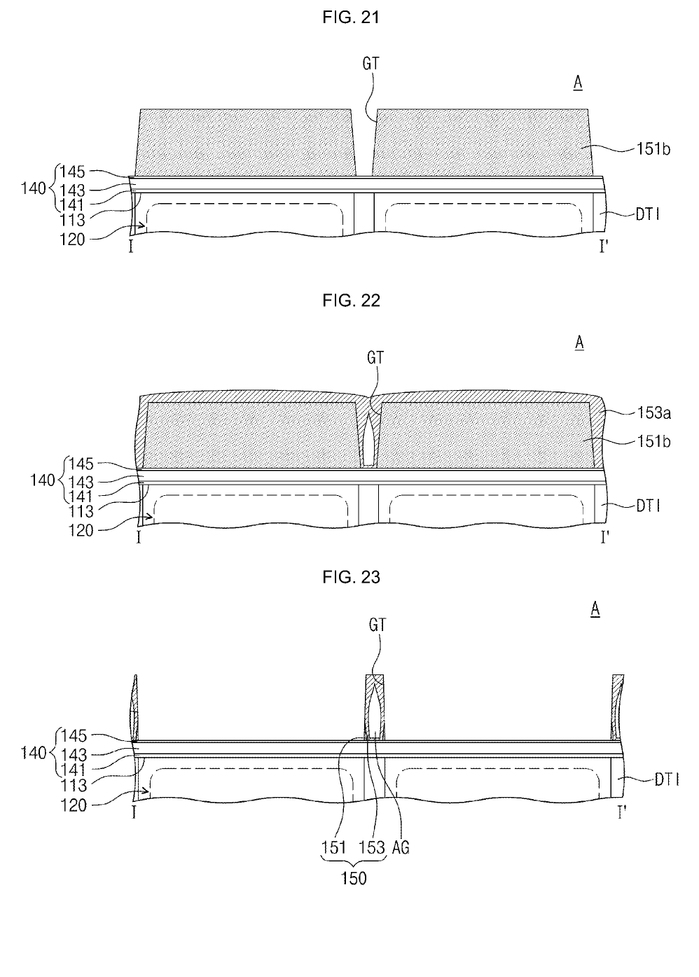

Referring to FIG. 21, a mask pattern, not illustrated, may be formed on the first pattern layer 151a. The mask pattern may have an opening that defines a grid trench structure GT. The opening may expose a portion of the first pattern layer 151a. The first pattern layer 151a may be etched using the mask pattern as an etch mask to form a grid trench GT within the first pattern layer 151a. In one or more embodiments, the first pattern layer 151a may include an insulating material such as a silicon oxide.

In one or more embodiments, an etching process of forming the grid trench GT may be performed until the capping layer 145 is exposed. The exposed surface of the capping layer 145 may correspond to a bottom surface of the grid trench GT. In one or more embodiments, a level of the bottom surface of the grid trench GT may be substantially the same as a level of an upper surface of the capping layer 145. The mask pattern may be removed after the formation of the grid trench structure GT. The etched first pattern layer 151a may be now referred to as first pattern 151b.

Referring to FIG. 22, a second pattern layer 153a may be formed on the first pattern layer 151b having the grid trench GT. A portion of the second pattern layer 153a may fill the grid trench GT. For example, the second pattern layer 153a may be formed using a deposition process. In one or more embodiments, the second pattern layer 153a may include an insulating material containing phosphorus (P) and/or boron (B) elements or an insulating material doped with phosphorus (P) and/or boron (B) elements, and may include a silicon oxide containing or doped with at least one of phosphorus (P) or boron (B) elements.

Referring to FIG. 23, a planarization process may be performed on the first pattern layer 151b and the second pattern layer 153a. The planarization process may be performed until the first pattern layer 151b is exposed or until a portion of the first pattern layer 151b is overetched. After the planarization process, a mask pattern, not illustrated, may be formed on the first pattern layer 151b. The mask pattern may have an opening that defines the grid 150. The opening may expose the first pattern layer 151b. The first pattern layer 151b may be etched using the mask pattern as an etch mask to form the grid 150 including the first pattern 151, the second pattern 153, and the air gap AG.

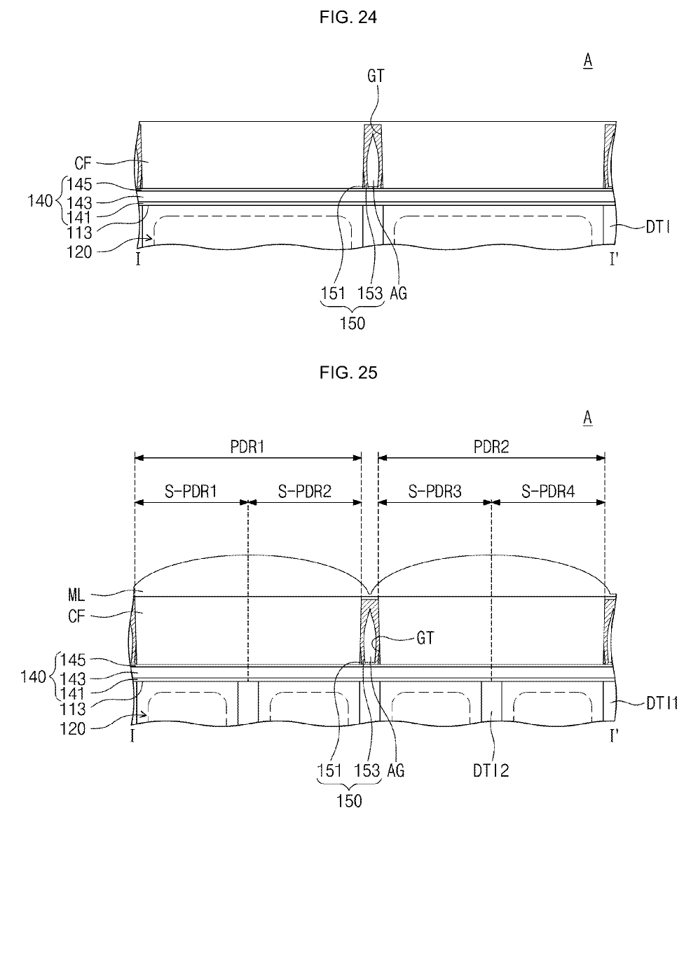

Referring to FIG. 24, color filters CF may be formed on the capping layer 145. The grid 150 may have openings that define the positions of the color filters CF, so that the color filters CF may be provided in the openings of the grid 150 to be formed on the capping layer 145.

The method of manufacturing the image sensors of FIGS. 6 and 8 according to one or more embodiments may further include a patterning process of forming a recess region RR (for example, a process of forming a mask pattern and an etching process using the mask pattern as an etch mask). The patterning process of forming the recess region RR may be performed after the grid trench structure GT is formed according to FIG. 21, but embodiments are not limited thereto.

The image sensor of FIG. 9 according to one or more embodiments may be manufactured by forming color filters CF using a first pattern layer 151b as a sacrificial grid layer or sacrificial grid and depositing the second pattern layer 151a. Alternatively, the image sensor of FIG. 9 may be manufactured by depositing a grid layer, not illustrated, followed by formation of color filters CF with a certain spacing therebetween.

FIG. 25 is a cross-sectional view of an image sensor according to one or more embodiments. Hereinafter, differences from the above-described embodiments will be mainly described for clarity.

Referring to FIG. 25, an image sensor according to one or more embodiments may further include a second deep trench isolation pattern DTI2. The second deep trench isolation pattern DTI2 may be formed within a first substrate 110. The second deep trench isolation pattern DTI2 may be provided within each photodiode region PDR.

The second deep trench isolation pattern DTI2 may define a pair of sub-photodiode regions S-PDR1 and S-PDR2. The pair of sub-photodiode regions S-PDR1 and S-PDR2 may be included in a photodiode region PDR1. For example, the second deep trench isolation pattern DTI2 may be provided between the pair of sub-photodiode regions S-PDR1 and S-PDR2.

A photodiode 120 may be provided within each of the sub-photodiode regions S-PDR1 to S-PDR4. In one or more embodiments, the photodiodes 120 provided within each of the sub-photodiode regions S-PDR1 to S-PDR4 may be regions doped with different materials. However, embodiments are not limited thereto, and the photodiodes 120 provided within each of the pair of sub-photodiode regions may be regions doped with substantially the same material.

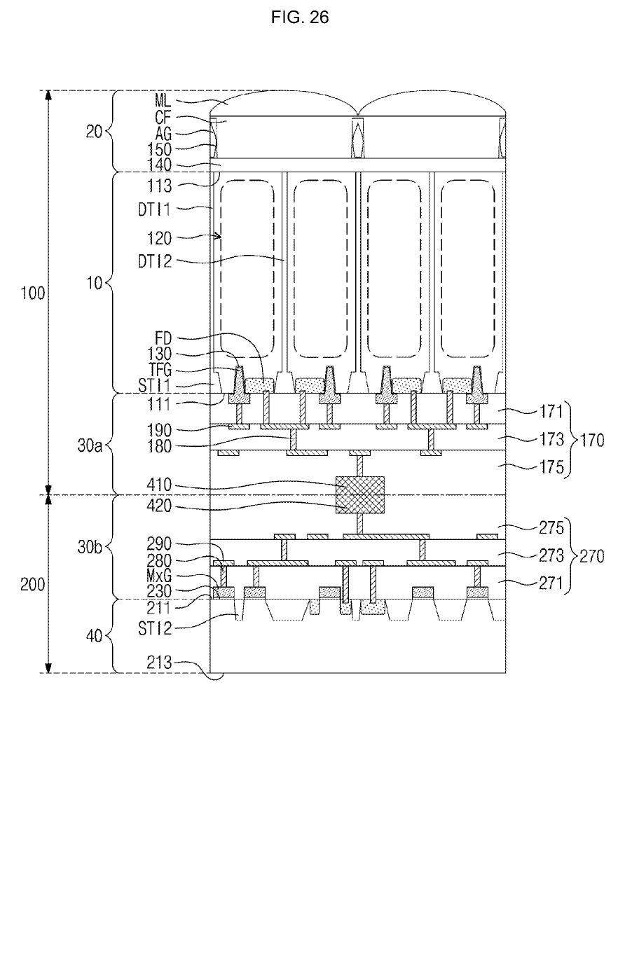

FIG. 26 is a cross-sectional view of an image sensor according to one or more embodiments.

Referring to FIG. 26, an image sensor according to one or more embodiments may include first and second structures 100 and 200. The first structure 100 may be stacked on the second structure 200. For example, the image sensor according to one or more embodiments may have a stacked structure. The first structure 100 may be referred to as a photoelectric conversion structure, and the second structure 200 may be referred to as a peripheral circuit structure. The first structure 100 and the second structure 200 may be bonded to each other by at least one of various bonding methods and may be electrically connected to each other by at least one of various connection methods.

The first structure 100 may include an optical control layer 20, a photoelectric conversion layer 10, and a first wiring layer 30a. The photoelectric conversion layer 10 may be disposed between the optical control layer 20 and the first wiring layer 30a.

The optical control layer 20 may include microlenses ML, color filters CF, a light transmitting layer 140, and a grid 150. The photoelectric conversion layer 10 may include a first substrate 110, photodiodes 120, a first deep trench isolation pattern DTI1, a second deep trench isolation pattern DTI2, a first shallow trench isolation pattern STI1, floating diffusion regions FD, first gate insulating layers 130, and transfer gates TFG. The first wiring layer 30a may include first interlayer dielectrics 170, first contact plugs 180, first wirings 190, and a first bonding pad 410.

The first interlayer dielectrics 170 may be provided on a first surface 111 of the first substrate 110. The first interlayer dielectrics 170 may cover the first surface 111, the floating diffusion regions FD, and the transfer gates TFG. For example, each of the first interlayer dielectrics 170 may include at least one of a silicon oxide, a silicon oxynitride, or a silicon nitride. In one or more embodiments, the first interlayer dielectrics 170 may be sequentially stacked on the first surface 111 of the first substrate 110. The first contact plugs 180 and the first wirings 190 may be provided within the first interlayer dielectrics 170.

The first bonding pad 410 may be disposed within a lowermost interlayer dielectric 165 among the first interlayer dielectrics 170.

The second structure 200 may include a peripheral circuit layer 40 and a second wiring layer 30b.

The peripheral circuit layer 40 may include a second substrate 210, a second shallow trench isolation pattern STI2, a second gate insulating layer 230, and peripheral circuit gates MxG. The second wiring layer 30b may include second interlayer dielectrics 270, second contact plugs 280, second wirings 290, and a second bonding pad 420.

The second substrate 210 may have a third surface 211 and a fourth surface 213 opposing the third surface 211. The third surface 211 may be a front surface of the second substrate 210, and the fourth surface 213 may be a rear surface of the second substrate 210. The second shallow trench isolation pattern STI2 may be disposed within a shallow trench recessed to a specific depth from the third surface 211 of the second substrate 210.

The second shallow trench isolation pattern STI2 may define active regions within the second substrate 210. The second shallow trench isolation pattern STI2 may be adjacent to the third surface 211 of the second substrate 210.

The peripheral circuit gates MxG may be disposed on corresponding active regions of the second substrate 210. In one or more embodiments, the peripheral circuit gates MxG may be disposed on the third surface 211 of the second substrate 210. The second gate insulating layer 230 may be disposed between the peripheral circuit gates MxG and the corresponding active regions. Peripheral circuit source/drain regions may be disposed within the corresponding active regions on opposite sides of each of the peripheral circuit gates MxG.

The second interlayer dielectrics 270 may be disposed on the third surface 211 of the second substrate 210 to cover the third surface 211, the second gate insulating layer 230, and the peripheral circuit gates MxG. The second interlayer dielectrics 270 may be sequentially stacked on the third surface 211 of the second substrate 210. The second contact plugs 280 and the second wirings 290 may be provided within the second interlayer dielectrics 270. The second bonding pad 420 may be disposed within an uppermost interlayer dielectric 275 among the second interlayer dielectrics 270.

The first and second bonding pads 410 and 420 may electrically connect the first and second structures 100 and 200. In one or more embodiments, the first bonding pad 410 and the second bonding pad 420 may be bonded to each other to electrically connect the first structure 100 and the second structure 200. In one or more embodiments, the first and second bonding pads 410 and 420 may include copper. The first and second bonding pads 410 and 420 may be bonded to each other using a copper-to-copper bonding technique. The bonded bonding pads 410 and 420 may form a single body without an interface therebetween. In one or more embodiments, a lowermost interlayer dielectric 175 among the first interlayer dielectrics may be bonded to an uppermost interlayer dielectric 275 among the second interlayer dielectrics through covalent bonding.

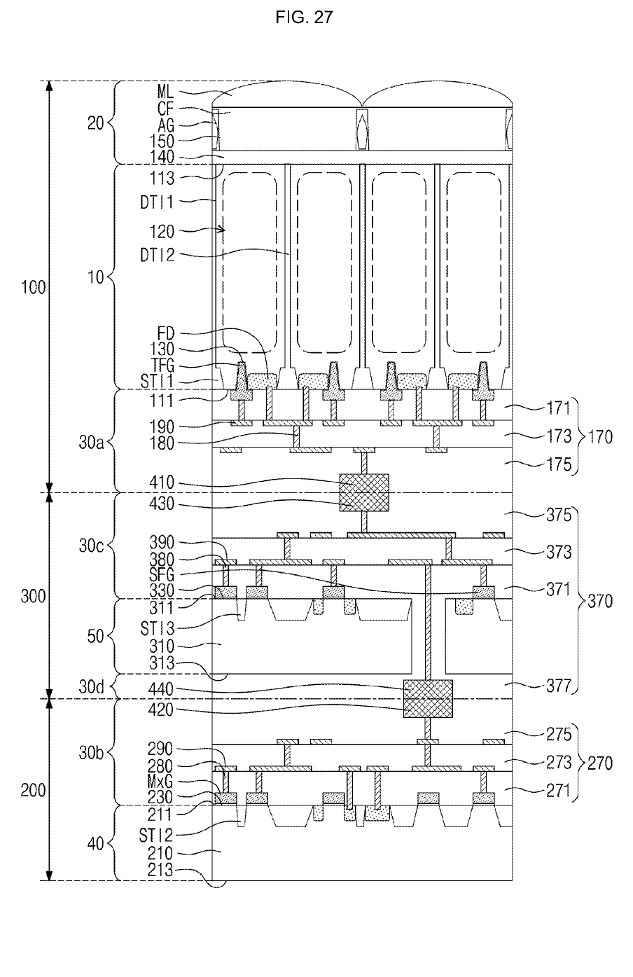

FIG. 27 is a cross-sectional view of an image sensor according to one or more embodiments.

Referring to FIG. 27, an image sensor according to one or more embodiments may include first to third structures 100, 200, and 300. The first structure 100 may be stacked on a third structure 300, and the third structure 300 may be stacked on a second structure 200. For example, the third structure 300 may be disposed between the first structure 100 and the second structure 200. The third structure 300 may be referred to as an intermediate structure. The first structure 100 and the second structure 200 may be bonded to each other by at least one of various bonding methods and may be electrically connected to each other by at least one of various connection methods. The second structure 200 and the third structure 300 may be bonded to each other by at least one of various bonding methods and may be electrically connected to each other by at least one of various connection methods.

The third structure 300 may include an intermediate layer 50, a third wiring layer 30c, and a fourth wiring layer 30d. The intermediate layer 50 may be disposed between the third wiring layer 30c and the fourth wiring layer 30d.

The intermediate layer 50 may include a third substrate 310, a third shallow trench isolation pattern STI3, a third gate insulating layer 330, and gates. The third wiring layer 30c may include at least one of the third interlayer dielectrics 370, third contact plugs 380, third wirings 390, and a third bonding pad 430. The fourth wiring layer 30d may include at least another one of the third interlayer dielectrics 370, and a fourth bonding pad 440.

The third substrate 310 may have a fifth surface 311 and a sixth surface 313 opposing the fifth surface 311. The fifth surface 311 may be a front surface of the third substrate 310, and the sixth surface 313 may be a rear surface of the third substrate 310. Conversely, the fifth surface 311 may be a rear surface of the third substrate 310, and the sixth surface 313 may be a front surface of the third substrate 310.

The third shallow trench isolation pattern STI3 may be disposed within a shallow trench recessed to a specific depth from the fifth surface 311 of the third substrate 310. The third shallow trench isolation pattern STI3 may define active regions within the third substrate 310. In one or more embodiments, the third shallow trench isolation pattern STI3 may be adjacent to the fifth surface 311 of the third substrate 210.

Gates (for example, reset gate, select gate, source follower gate SFG, or the like) may be disposed on corresponding active regions of the third substrate 310. In one or more embodiments, the reset gate, the select gate, and the source follower gate SFG may be disposed on the fifth surface 311 of the third substrate 310. The third gate insulating layer 330 may be disposed between each of the reset gate, the select gate, and the source follower gate SFG and the corresponding active region. Source/drain regions may be disposed within the corresponding active regions on opposite sides of each of the gates.

At least one of the third interlayer dielectrics 370 may be disposed on the fifth surface 311 of the third substrate 310 to cover the fifth surface 311, the third gate insulating layer 330, and the reset gate, selection gate, and source follower gate SFG. In one or more embodiments, a plurality of third interlayer dielectrics 370 may be sequentially stacked on the fifth surface 311 of the third substrate 310. At least another one of the third interlayer dielectrics 370 may be disposed on the sixth surface 313 of the third substrate 310. For example, the third interlayer dielectric 377 may be disposed on the sixth surface 313 of the third substrate 310. Contact plugs 380 and third wirings 390 may be provided within the third interlayer dielectrics 370.

The third bonding pad 430 may be disposed within an uppermost interlayer dielectric 375 among the third interlayer dielectrics 370, and the fourth bonding pad 440 may be disposed within a lowermost interlayer dielectric 377 among the third interlayer dielectrics 370.

The first to fourth bonding pads 410, 420, 430, and 440 may electrically connect the first to third structures 100, 200, and 300. In one or more embodiments, the first bonding pad 410 and the third bonding pad 430 may be bonded to each other to electrically connect the first structure 100 and the third structure 300. In one or more embodiments, the second bonding pad 420 and the fourth bonding pad 440 may be bonded to each other to electrically connect the second structure 200 and the third structure 300.

In one or more embodiments, the third structure 300 may be bonded differently from what is illustrated in FIG. 26 by applying vertical inversion, vertical and horizontal inversion, or rotation by 180 degrees. For example, the first bonding pad 410 and the fourth bonding pad 440 may be bonded to each other to electrically connect the first structure 100 and the third structure 300. For example, the second bonding pad 420 and the third bonding pad 430 may be bonded to each other to electrically connect the second structure 200 and the third structure 300.

In one or more embodiments, the third and fourth bonding pads 430 and 440 may include copper, similarly to the first and second bonding pads 410 and 420. Among the first to fourth bonding pads 410, 420, 430, and 440, pads bonded to each other may use a copper-to-copper bonding technique to form a single body without an interface therebetween.

In one or more embodiments, among the first to third interlayer dielectrics 170, 270, and 370, bonded interlayer dielectrics may be covalently bonded to each other. For example, a lowermost interlayer dielectric 175 among the first interlayer dielectrics 170 may be bonded to an uppermost interlayer dielectric 375 among the third interlayer dielectrics 370. For example, an uppermost interlayer dielectric 275 among the second interlayer dielectrics 270 may be bonded to a lowermost interlayer dielectric 377 among the third interlayer dielectrics 370.

In one or more embodiments, when the third structure 300 is inverted and bonded (not illustrated; for example, vertically inverted, vertically and horizontally inverted, or rotated by 180 degrees), the lowermost interlayer dielectric 175 among the first interlayer dielectrics 170 may be bonded to the uppermost interlayer dielectric 377 among the third interlayer dielectrics 370, and the uppermost interlayer dielectric 275 among the second interlayer dielectrics 270 may be bonded to the lowermost interlayer dielectric 375 among the third interlayer dielectrics 370.

As set forth above, according to one or more embodiments, an air gap having a large space may be formed.

While various embodiments have been shown and described above, it will be apparent to those skilled in the art that modifications and variations could be made without departing from the scope of the present invention as defined by the appended claims.

What is claimed is:

1. An image sensor comprising:
a substrate having a first surface and a second surface opposing the first surface and comprising photodiode regions spaced apart from each other;
a light transmitting layer covering the second surface;
a grid disposed on the light transmitting layer, the grid comprising a first pattern, a second pattern , wherein an adhesion coefficient of the second pattern is greater than an adhesion coefficient of the first pattern;
an air gap formed in an internal space defined by at least the second pattern;
color filters filling openings defined by the grid; and
microlenses disposed on the color filters.

2. The image sensor of claim 1, wherein:
the first pattern is formed of a first insulating material; and
the second pattern is formed of a second insulating material doped with dopants or dopant elements that increase the adhesion coefficient of the second insulating material.

3. The image sensor of claim 2, wherein
the second pattern is formed of the second insulating material doped with phosphorus (P) elements.

4. The image sensor of claim 2, wherein:
the second pattern is formed of the second insulating material doped with boron (B) elements.

5. The image sensor of claim 1, wherein:
the first pattern comprises a grid trench structure defining a grid trench; and
a first portion of the second pattern is provided in the grid trench to define a portion of the air gap, and a second portion of the second pattern closes an upper end of the air gap.

6. The image sensor of claim 1, wherein:
the air gap has a grid shape, a bar shape, or a dot shape in plan view.

7. The image sensor of claim 5, wherein:
the light transmitting layer includes a recessed region, and
the second pattern penetrates into the light transmitting layer and into the recessed region and defines the air gap so that the air gap extends into at least a portion of the recessed region.

8. The image sensor of claim 1, wherein:
the air gap is the only air gap of the grid, and
the air gap extends continuously throughout the grid.

9. The image sensor of claim 1, wherein:
the light transmitting layer comprises an antireflective layer having a recess region; and
the second pattern fills at least a portion of the recess region.

10. The image sensor of claim 1, wherein:
the air gap has a volume greater than half of a total volume of the grid.

11. An image sensor comprising:
a substrate having a first surface and a second surface opposing the first surface and comprising photodiode regions spaced apart from each other;
a light transmitting layer covering the second surface;
a grid disposed on the light transmitting layer, the grid comprising a first pattern, a second pattern,, and the second pattern comprising phosphorus (P) elements;
an air gap enclosed within the grid;
color filters filling openings defined by the grid; and
microlenses disposed on the color filters.

12. The image sensor of claim 11, wherein:
the second pattern further comprises boron (B) elements.

13. The image sensor of claim 11, wherein:
the first pattern forms a grid trench structure defining a grid trench;
a first portion of the second pattern is provided in the grid trench to define the air gap; and
a second portion of the second pattern closes an upper end of the air gap.

14. The image sensor of claim 11, wherein:
the air gap has a grid shape, a bar shape, or a dot shape in plan view.

15. The image sensor of claim 11, wherein:
the light transmitting layer comprises an antireflective film having a recess region; and
the second pattern fills at least a portion of the recess region.

16. The image sensor of claim 11, wherein:
the air gap has a volume greater than half of a total volume of the grid.

17. The image sensor of claim 11, wherein:
the first and second patterns are formed of different materials.

18. An image sensor comprising:
a substrate having a first surface and a second surface opposing the first surface and comprising photodiode regions spaced apart from each other;
a light transmitting layer covering the second surface;
a grid disposed on the light transmitting layer, the grid comprising phosphorus (P) elements;
an air gap defined by, at least in part, the grid;
color filters filling openings of the grid; and
microlenses disposed on the color filters.

19. The image sensor of claim 18, wherein the air gap is defined by an internal space bounded by the grid, the color filter, and the light transmitting layer.

20. The image sensor of claim 18, wherein the air gap has a volume greater than half of a sum of a total volume of the grid and the volume the air gap.
